(19) United States
(12) Patent Application Publication
(10) Pub. No.: US 2024/0213982 A1
(43) Pub. Date: Jun. 27, 2024

(54) MULTIPLEXING CHANNEL SWITCH SELECTION CIRCUIT AND CONTROL CIRCUIT AND CONTROL METHOD THEREOF

(71) Applicant: TRITIUM ELECTRONICS PTE. LTD., Singapore (SG)

(72) Inventors: Zhi-Xin CHEN, Hsinchu County (TW); Pao-Cheng CHIU, Hsinchu County (TW)

(73) Assignee: TRITIUM ELECTRONICS PTE. LTD., (omitted)

(21) Appl. No.: 18/536,197

(22) Filed: Dec. 11, 2023

Related U.S. Application Data
(60) Provisional application No. 63/476,631, filed on Dec. 21, 2022.

(30) Foreign Application Priority Data
Apr. 20, 2023 (CN) 202310429745.9

(51) Int. Cl. H03K 17/70

(52) U.S. Cl. CPC H03K 17/70

(57) ABSTRACT

A multiplexing channel switch selection circuit includes: plural channel switch circuits coupled to plural corresponding input ends and plural channel switch circuits are commonly coupled to an output end. Each channel switch circuit comprises: a switch unit and a control circuit. The control circuit includes: an analog bootstrap circuit coupled between the shared source end and the shared gate end, wherein in a situation when the channel selection signal selects the each channel switch circuit, the analog bootstrap circuit supplies an conductive bias voltage across between the shared source end and the shared gate end, to turn ON the first switch and the second switch; and a feedback regulation circuit coupled to the analog bootstrap circuit, wherein the feedback regulation circuit feedback-regulates the shared gate voltage at a constant voltage level.

### CROSS REFERENCE

The present invention claims priority to the U.S. provisional patent application Ser. No. 63/476,631, filed on Dec. 21, 2022 and claims priority to the CN patent application Ser. No. 202310429745.9, filed on Apr. 20, 2023, all of which foregoing mentioned provisional and nonprovisional patent applications are incorporated herein in their entirety by their reference.

### BACKGROUND OF THE INVENTION

### Field of Invention

The present invention relates to a multiplexing channel switch selection circuit; particularly, it relates to such multiplexing channel switch selection circuit having capacity to measure voltage signals with high precision, especially when being applied in a high-voltage cell module. The present invention also relates to a control circuit and a control method of such multiplexing channel switch selection circuit.

### Description of Related Art

Please refer to FIG. 1, which shows a schematic diagram of a prior art channel switch circuit 110. The prior art channel switch circuit 110 includes: a first switch Q1 and a second switch Q2 (both of which are connected in series between an input voltage and an output voltage), a resistor R1, a current source IS1 and a switch selection circuit 111.

For the sake of accomplishing a multiplexing voltage measurement in a high-voltage cell module, the prior art channel switch circuit 110 will employ a multiplexing channel switch selection circuit, thus carrying out the requirement of withstanding a high-voltage and the requirement of a relatively smaller area. A high-voltage cell module is typically applied in a high-current having its current level to be within an ampere scope, particularly, in a cell system of vehicle. The prior art multiplexing channel switch selection circuit includes: plural channel switch circuits, wherein a control circuit of each channel switch circuit is the most pivotal factor which will impinge an area and a precision of measuring cell voltages. It is worthwhile noting that: because the high-voltage cell module is constituted by having a concatenation of plural cell modules to be sequentially connected in series to each other, it is required for the high-voltage cell module to adopt the multiplexing channel switch selection circuit having the plural channel switch circuits, so that the concatenation of plural cell modules respectively correspond to the plural channel switch circuits, especially for a high-voltage cell module in a vehicle and an energy storage system.

The prior art channel switch circuit 110 shown in FIG. 1 is a commonplace channel switch circuit. As shown in FIG. 1, the prior art channel switch circuit 110 utilizes the current source IS1 and the resistor R1, wherein the resistor R1 is electrically connected between a gate and a source of the first switch Q1 and a gate and a source of the second switch Q2. When a channel selection signal Sct selects the each channel switch circuit 110, a gate-source voltage of the first switch Q1 and a gate-source voltage of the second switch Q2 is gained via a product of a current level of a current provided by the current source IS1 multiplied by a resistance of the resistor R1, so as to turn ON the first switch Q1 and the second switch Q2. In a case when the first switch Q1 and the second switch Q2 are required to be turned OFF, an inverse phase signal Sctn of the channel selection signal Sct serves to turn OFF the first switch Q1 and the second switch Q2 by pulling down a gate voltage of the first switch Q1 and a gate voltage of the second switch Q2 to a ground potential GND.

The prior art shown in FIG. 1 has following numerous defects that: firstly, an impedance of an input end having the input voltage Vin thereat is unwantedly reduced; secondly, the current source IS1 is undesirably impinged by a channel effect; thirdly, the gate-source voltage is unwantedly sensitive to a temperature; the current provided by the current source IS1 will unpleasantly flow along between the first switch Q1 and the second switch Q2, thereby incurring voltage measurement errors; and finally, it is accessible for a switch input current to unwantedly incur imbalance among cell voltages.

In view of the above, to overcome the defects in the prior art shown in FIG. 1, please refer to FIG. 2, which shows a schematic circuit diagram of an ameliorated prior art multiplexing channel switch selection circuit 210 disclosed in U.S. Pat. No. 9,407,250 B2. As shown in FIG. 2, a channel switch circuit 210 exploits a dummy switch 211 to prevent a current provided by a current source from unpleasantly flowing into the first switch Q1 and the second switch Q2. Additionally, the channel switch circuit 210 exploits the dummy switch 211 to prevent an unwanted issue of imbalance among cell voltages resulted from an input end having an input voltage Vin thereat from transpiring.

In view of the above, to overcome the defects in the prior art shown in FIG. 1, please refer to FIG. 3, which shows a schematic circuit diagram of another ameliorated prior art multiplexing channel switch selection circuit disclosed in U.S. Publication Patent No. 20140043032A1. As shown in FIG. 3, the prior art multiplexing channel switch selection circuit 310 disclosed in U.S. Publication Patent No. 20140043032A1 employs a source follower to augment an input impedance, while in the meantime the prior art multiplexing channel switch selection circuit 310 prevents a current provided by a current source from unpleasantly flowing into the first switch Q1 and the second switch Q2. Besides, the prior art multiplexing channel switch selection circuit 310 prevents the first switch Q1 and the second switch Q2 from being influenced by a current generated by a current source. Nevertheless, the ameliorated prior arts shown in FIG. 2 and FIG. 3 still have following defects that: firstly, the current source IS1 remains undesirably impinged by a channel effect; and secondly, the gate-source voltage remains unwantedly sensitive to a temperature. Consequently, in this case, high precision of the voltage signals measurement will be undesirably curtailed.

As compared to the prior arts shown in FIG. 1 to FIG. 3, the present invention proposes a multiplexing channel switch selection circuit and a control circuit and a control method thereof, which is advantageous over the prior arts shown in FIG. 1 to FIG. 3, in that: the present invention is well capable of adaptively feedback-regulating a shared gate voltage based upon an alteration of the shared gate voltage, such that the shared gate voltage has capacity to be retained at a fixed voltage level.

### SUMMARY OF THE INVENTION

From one perspective, the present invention provides a multiplexing channel switch selection circuit, including: a plurality of channel switch circuits, wherein the plurality of the channel switch circuits are coupled to a plurality of corresponding input ends and the plurality of the channel switch circuits are commonly coupled to an output end; each channel switch circuit comprising: a switch unit including: a first switch and a second switch, wherein the first switch and the second switch are connected in series to a current route which lies between the corresponding input end and the output end, wherein in a situation when a channel selection signal selects the each channel switch circuit, the switch unit is configured to operably turn ON the first switch and the second switch based upon a shared gate voltage, so as to deliver an input voltage at the corresponding input end to the output end, so that the thus delivered input voltage becomes an output voltage at the output end, wherein a gate of the first switch and a gate of the second switch are commonly coupled to a shared gate end having the shared gate voltage thereat, and wherein a source of the first switch and a source of the second switch are commonly coupled to a shared source end having a shared source voltage thereat; and a control circuit coupled between the shared source end and the shared gate end, wherein the control circuit includes: an analog bootstrap circuit coupled between the shared source end and the shared gate end, wherein in a situation when the channel selection signal selects the each channel switch circuit, the analog bootstrap circuit is configured to operably supply a conductive bias voltage across between the shared source end and the shared gate end, so as to turn ON the first switch and the second switch; and a feedback regulation circuit coupled to the analog bootstrap circuit, wherein the feedback regulation circuit is configured to operably feedback-regulate the shared gate voltage at a constant voltage level; wherein in the situation when the channel selection signal selects the each channel switch circuit and in a situation when the each channel switch circuit operates in a steady state, a current flowing through the current route is a zero current; wherein the shared gate voltage is equal to a sum of shared the source voltage plus the conductive bias voltage.

From another perspective, the present invention provides a control circuit of a multiplexing channel switch selection circuit, which is configured to operably control a channel switch circuit of the multiplexing channel switch selection circuit, wherein the multiplexing channel switch selection circuit, includes: a plurality of channel switch circuits, wherein the plurality of the channel switch circuits are coupled to a plurality of corresponding input ends and the plurality of the channel switch circuits are commonly coupled to an output end; and wherein each channel switch circuit further includes a switch unit having: a first switch and a second switch, wherein the first switch and the second switch are connected in series to a current route which lies between the corresponding input end and the output end, wherein in a situation when a channel selection signal selects the each channel switch circuit, the switch unit is configured to operably turn ON the first switch and the second switch based upon a shared gate voltage, so as to deliver an input voltage at the corresponding input end to the output end, so that the thus delivered input voltage becomes an output voltage at the output end, wherein a gate of the first switch and a gate of the second switch are commonly coupled to a shared gate end having the shared gate voltage thereat, and wherein a source of the first switch and a source of the second switch are commonly coupled to a shared source end having a shared source voltage thereat; the control circuit of the multiplexing channel switch selection circuit comprising: an analog bootstrap circuit coupled between the shared source end and the shared gate end, wherein in a situation when the channel selection signal selects the each channel switch circuit, the analog bootstrap circuit is configured to operably supply a conductive bias voltage across between the shared source end and the shared gate end, so as to turn ON the first switch and the second switch; and a feedback regulation circuit coupled to the analog bootstrap circuit, wherein the feedback regulation circuit is configured to operably feedback-regulate the shared gate voltage at a constant voltage level; wherein in the situation when the channel selection signal selects the each channel switch circuit and in a situation when the each channel switch circuit operates in a steady state, a current flowing through the current route is a zero current;

wherein the shared gate voltage is equal to a sum of shared the source voltage plus the conductive bias voltage.

From yet another perspective, the present invention provides a control method of a multiplexing channel switch selection circuit, which is configured to operably control a channel switch circuit of the multiplexing channel switch selection circuit, wherein the multiplexing channel switch selection circuit, includes: a plurality of channel switch circuits, wherein the plurality of the channel switch circuits are coupled to a plurality of corresponding input ends and the plurality of the channel switch circuits are commonly coupled to an output end; and wherein each channel switch circuit further includes a switch unit having: a first switch and a second switch, wherein the first switch and the second switch are connected in series to a current route which lies between the corresponding input end and the output end, wherein in a situation when a channel selection signal selects the each channel switch circuit, the switch unit is configured to operably turn ON the first switch and the second switch based upon a shared gate voltage, so as to deliver an input voltage at the corresponding input end to the output end, so that the thus delivered input voltage becomes an output voltage at the output end, wherein a gate of the first switch and a gate of the second switch are commonly coupled to a shared gate end having the shared gate voltage thereat, and wherein a source of the first switch and a source of the second switch are commonly coupled to a shared source end having a shared source voltage thereat; the control method of the multiplexing channel switch selection circuit comprising following steps: in a situation when the channel selection signal selects the each channel switch circuit, supplying a conductive bias voltage across between the shared source end and the shared gate end, so as to turn ON the first switch and the second switch; and feedback-regulating the shared gate voltage at a constant voltage level; wherein in the situation when the channel selection signal selects the each channel switch circuit and in a situation when the each channel switch circuit operates in a steady state, a current flowing through the current route is a zero current; wherein the shared gate voltage is equal to a sum of shared the source voltage plus the conductive bias voltage.

In one embodiment, an output impedance at the output end is relatively at least ten times greater than an input impedance at the each input end.

In one embodiment, the analog bootstrap circuit includes: an unidirectional voltage difference unit coupled between the shared source end and the shared gate end, wherein the unidirectional voltage difference unit is configured to operably supply the conductive bias voltage.

In one embodiment, the analog bootstrap circuit further includes: a Metal-Oxide-Semiconductor (MOS) device, wherein a gate of the MOS device is coupled to the shared source end, whereas, a source or a drain of the MOS device is coupled to the unidirectional voltage difference unit, wherein when the first switch and the second switch are both turned ON, the MOS device is turned ON, so that a threshold voltage of the MOS device as well as the unidirectional voltage difference unit are both configured to operably supply the conductive bias voltage.

In one embodiment, the unidirectional voltage difference unit includes: at least a PN diode, at least a Zener diode or at least a MOS diode.

In one embodiment, the feedback regulation circuit includes: a source follower coupled to the analog bootstrap circuit, wherein the source follower is configured to operably receive the shared source voltage, thus producing a feedback voltage; and an inverse phase amplification gain stage, wherein the source follower and the inverse phase amplification gain stage constitute a flipped voltage follower (FVF), wherein the FVF is configured to operably regulate the shared gate voltage at the constant voltage level.

In one embodiment, the feedback regulation circuit includes: a first current source, which is configured to operably provide a first current; a first current mirror coupled to the first current source, wherein the first current mirror is configured to operably generate a second current and a third current in a mirror fashion in accordance with the first current; a second current mirror coupled to the first current mirror as well as the inverse phase amplification gain stage, wherein the second current mirror is configured to operably generate a fourth current through mirroring the second current; and a second current source coupled to the first current source and the source follower, wherein the second current source is configured to operably generate a fifth current correlated with the first current according to the third current.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic diagram of a prior art channel switch circuit 110.

FIG. 2 shows a schematic circuit diagram of a prior art multiplexing channel switch selection circuit 210 disclosed in U.S. Pat. No. 9,407,250 B2.

FIG. 3 shows a schematic circuit diagram of a prior art multiplexing channel switch selection circuit disclosed in U.S. Publication Patent No. 20140043032A1.

FIG. 4 shows a schematic circuit diagram of a multiplexing channel switch selection circuit 40 according to an exemplary embodiment of the present invention.

FIG. 5 shows a schematic diagram of a channel switch circuit 410 according to an exemplary embodiment of the present invention.

FIG. 6 shows a schematic diagram of a control circuit 412 according to an exemplary embodiment of the present invention.

FIG. 7 shows a schematic diagram of a feedback regulation circuit 4123 according to an exemplary embodiment of the present invention.

FIG. 8 shows a schematic diagram of a channel switch circuit 410 according to an exemplary embodiment of the present invention.

FIG. 9 shows a schematic diagram of a channel switch circuit 410 according to a specific exemplary embodiment of the present invention.

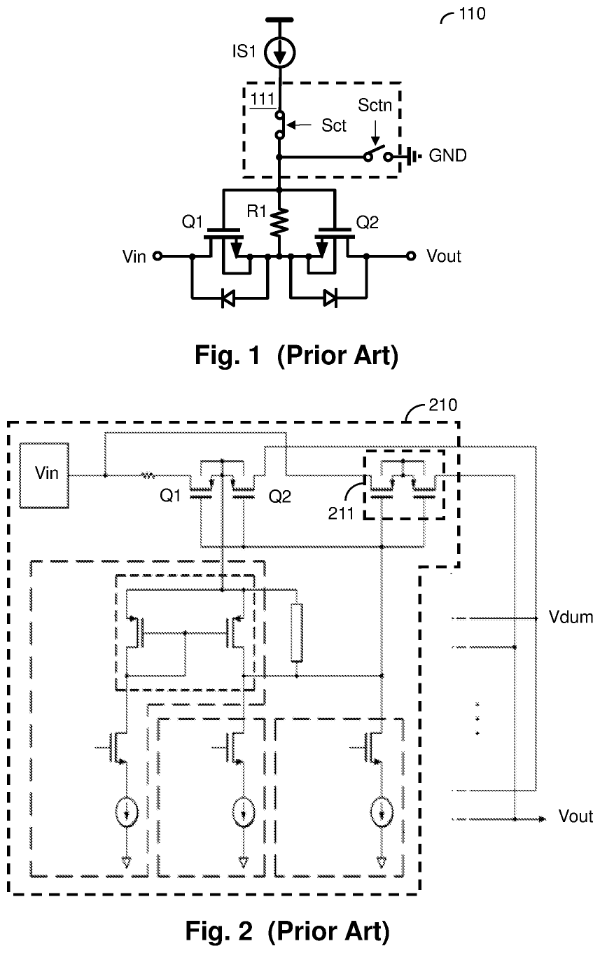

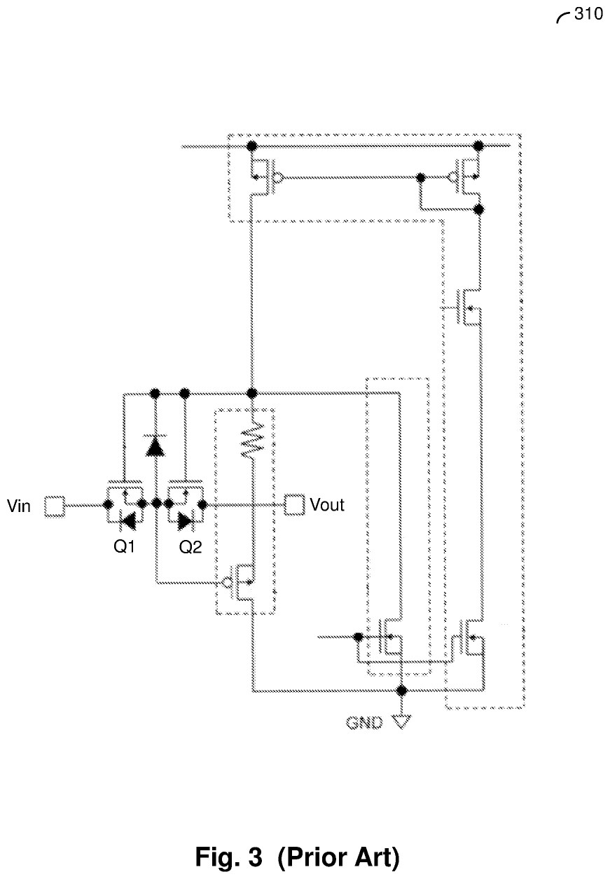

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

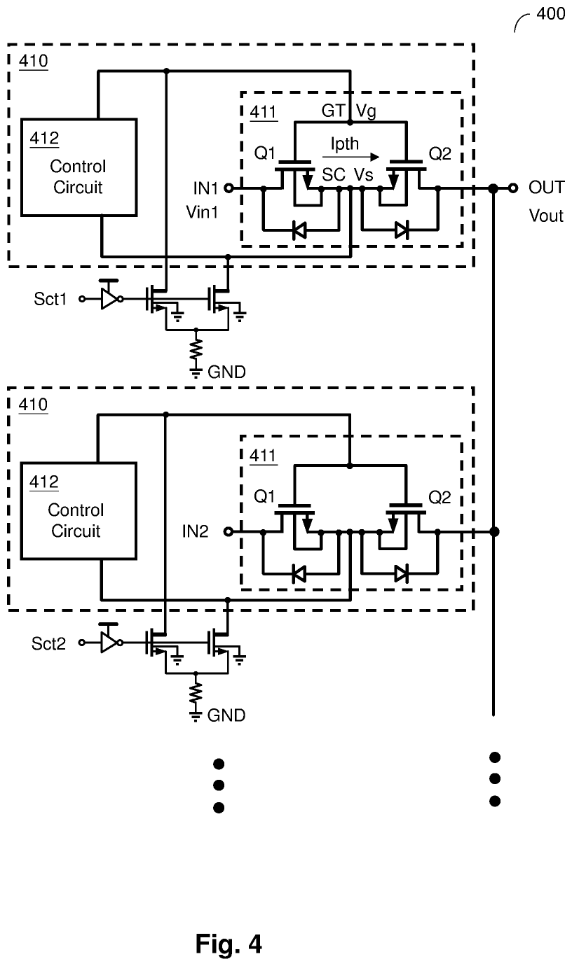

FIG. 4 shows a schematic circuit diagram of a multiplexing channel switch selection circuit 40 according to an exemplary embodiment of the present invention. As shown in FIG. 4, the multiplexing channel switch selection circuit 400 includes: plural channel switch circuits 410, wherein the plural channel switch circuits 410 are coupled to plural input ends IN1, IN2, . . . and the plural channel switch circuits 410 are commonly coupled to an output end OUT. As exemplified by the channel switch circuits 410 illustrated as being located at the most top portion of FIG. 4, this channel switch circuits 410 includes: a switch unit 411 and a control circuit 412. The switch unit 411 includes: a first switch Q1 and a second switch Q2, wherein the first switch Q1 and the second switch Q2 are connected in series to a current route Ipth which lies between the corresponding input end IN1 and the output end OUT. In a situation when a channel selection signal Sct1 (note that, for the channel switch circuits 410 illustrated as being located at the bottom portion of FIG. 4, a channel selection signal corresponding to such channel switch circuits 410 will be a channel selection signal Sct2) selects the channel switch circuit 410 (i.e., the channel switch circuits 410 illustrated as being located at the most top portion of FIG. 4), the switch unit 411 is configured to operably turn ON the first switch Q1 and the second switch Q2 based upon a shared gate voltage Vg, so as to deliver an input voltage Vin1 at the corresponding input end IN1 to the output end OUT, so that the thus delivered input voltage Vin1 becomes an output voltage Vout at the output end OUT. On one hand, a gate of the first switch Q1 and a gate of the second switch Q2 are commonly coupled to a shared gate end GT having the shared gate voltage Vg thereat. On the other hand, a source of the first switch Q1 and a source of the second switch Q2 are commonly coupled to a shared source end SC having a shared source voltage Vs thereat. The control circuit 412 is coupled between the shared source end SC and the shared gate end GT. Note that, in the situation when the channel selection signal Sct1 selects the channel switch circuit 410 and in a situation when the channel switch circuit 410 operates in a steady state, a current flowing through the current route Ipth is a zero current.

In one embodiment, each of the first switch Q1 and the second switch Q2 is, for example but not limited to, a P-type or an N-type Lateral Diffused MOSFET (LDMOS). As shown in FIG. 4, when the channel selection signal Sct1 is at a logic high level, indicating that the channel selection signal Sct1 selects the channel switch circuit 410 (i.e., the channel switch circuits 410 illustrated as being located at the “most top” portion of FIG. 4) to be turned ON. As a consequence, in this case, the input voltage Vin1 at the corresponding input end IN1 is delivered to the output end OUT, so that the thus delivered input voltage Vin1 becomes the output voltage Vout at the output end OUT. In this embodiment, when the channel selection signal Sct1 is at a logic low level, indicating that the shared source end SC and the shared gate end GT are both electrically connected to a ground potential GND. As a result, in this situation, the channel switch circuit 410 (i.e., the channel switch circuits 410 illustrated as being located at the “most top” portion of FIG. 4) is turned OFF, such that the input end IN1 will not be delivered to the output end OUT.

It is worthwhile noting that: in this embodiment shown in FIG. 4 and the following embodiments hereinafter, the N-type MOS device and the P-type MOS device are interchangeable, with corresponding amendments of the connection approach and with corresponding attention upon matching relationships among the MOS devices, which is well known to those skilled in the art, so the details thereof are not redundantly explained here.

In one embodiment, the multiplexing channel switch selection circuit 400 is configured to operably measure cell voltage, so the output end OUT will be coupled to a circuitry (e.g., an input end of an amplifier) having a high-impedance. In the multiplexing channel switch selection circuit 400 according to the present invention, between the first switch Q1 and the second switch Q2, the shared gate end GT and the shared source end SC are not directly and electrically connected to each other, while in the meantime the shared gate end GT and the shared source end SC are not directly and electrically connected to each other via a resistor and/or a current source. Consequently, in this case, as compared to the prior arts when a precision of the measured voltage is unwantedly reduced resulted from the measurement of a cell voltage is impinged due to a current is generated between the gate and the source of a switch in the switch unit, the multiplexing channel switch selection circuit 400 of the present invention is well capable of preventing the foregoing defects described in the prior arts from transpiring. In one embodiment, an output impedance at the output end OUT is relatively at least ten times greater than an input impedance at the input end IN1.

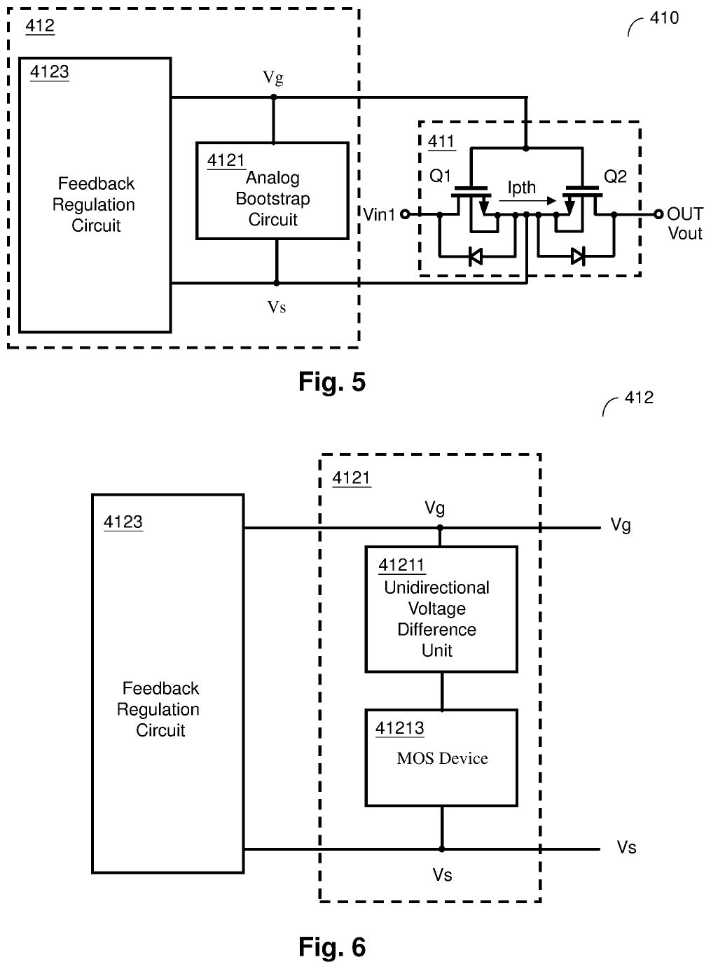

FIG. 5 shows a schematic diagram of a channel switch circuit 410 according to an exemplary embodiment of the present invention. As shown in FIG. 5, each channel switch circuit 410 incudes: a switch unit 411 and a control circuit 412. Because the switch unit 411 of this embodiment shown in FIG. 5 is similar to the switch unit 411 of the embodiment shown in FIG. 4, in regard to the details and features of the switch unit 411 of this embodiment shown in FIG. 5, please refer to the detailed elaborations of the foregoing embodiment with reference to FIG. 4, so the details thereof are not redundantly repeated here.

In this embodiment, a control circuit 412 includes: an analog bootstrap circuit 4121 and a feedback regulation circuit 4123. As shown in FIG. 5, the analog bootstrap circuit 4121 is coupled between the shared source end SC and the shared gate end GT. In a situation when the channel selection signal Sct1 selects this channel switch circuit 410, the analog bootstrap circuit 4121 is configured to operably supply a conductive bias voltage Vc across between the shared source end SC and the shared gate end GT, so as to turn ON the first switch Q1 and the second switch Q2. The conductive bias voltage Vc is a constant voltage difference which is floating to the shared source end SC, so that in a case when a source and a drain of the first switch Q1 and a source and a drain of the second switch Q2 are coupled to a high-voltage, the conductive bias voltage Vc serves to supply a gate voltage corresponding to the first switch Q1 and a gate voltage corresponding to the second switch Q2, thus turning ON the first switch Q1 and the second switch Q2 by each own corresponding gate voltage.

The feedback regulation circuit 4123 is coupled to the analog bootstrap circuit 4121, wherein the feedback regulation circuit 4123 is configured to operably feedback-regulate the shared gate voltage Vg at a constant voltage level. Moreover, in the situation when the channel selection signal Sct1 selects the channel switch circuit 410 and in a situation when the channel switch circuit 410 operates in a steady state, a current flowing through the current route Ipth is a zero current. The shared gate voltage Vg is equal to a sum of shared the source voltage Vs plus the conductive bias voltage Vc. When the channel switch circuit 410 operates in a steady state, it indicates that the input voltage Vin1 has already been delivered to the output end OUT, so that the thus delivered input voltage Vin1 becomes the output voltage Vout at the output end OUT, thus computing a voltage level of the input voltage Vin1 by providing the output voltage Vout to downstream circuits. Consequently, in this case, a scenario when the current flowing through the current route Ipth is a zero current has a capacity to augment a precision of the voltage level of the input voltage Vin1 computed via the downstream circuits.

FIG. 6 shows a schematic diagram of a control circuit 412 according to an exemplary embodiment of the present invention. In this embodiment, a control circuit 412 includes:

an analog bootstrap circuit 4121 and a feedback regulation circuit 4123. This embodiment serves to demonstrate that the analog bootstrap circuit 4121 includes: an unidirectional voltage difference unit 41211 and a MOS device 41213. The unidirectional voltage difference unit 41211 is coupled between the shared source end SC and the shared gate end GT, wherein the unidirectional voltage difference unit 41211 is configured to operably supply the conductive bias voltage Vc. A specific embodiment of the unidirectional voltage difference unit 41211 can be implemented as including, for example but not limited to, at least a PN diode, at least a Zener diode or at least a MOS diode. The major feature of the unidirectional voltage difference unit 41211 lies in that: the unidirectional voltage difference unit 41211 is unidirectionally turned ON and has a constant ON voltage. Furthermore, the unidirectional voltage difference unit 41211 adopted by the present invention has a temperature compensation relationship with the first switch Q1, whereas, the unidirectional voltage difference unit 41211 adopted by the present invention has another temperature compensation relationship with the second switch Q2, thereby compensating a temperature-dependent variation of the shared gate voltage Vg of the first switch Q1 and the second switch Q2.

A gate of MOS device 41213 is coupled to the shared gate end SC, whereas, a source or a drain of the MOS device 41213 is coupled to the unidirectional voltage difference unit 41211. When the first switch Q1 and the second switch Q2 are both turned ON, the MOS device 41213 is turned ON, so that a threshold voltage of the MOS device 41213 as well as the unidirectional voltage difference unit 41211 are both configured to operably supply the conductive bias voltage Vc.

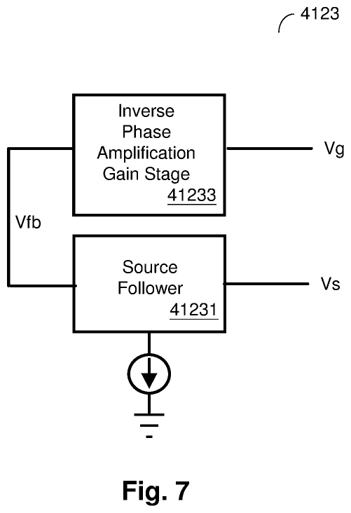

FIG. 7 shows a schematic diagram of a feedback regulation circuit 4123 according to an exemplary embodiment of the present invention. In this embodiment, the feedback regulation circuit 4123 includes: a source follower 41231 and an inverse phase amplification gain stage 41233. The source follower 41231 is coupled to the analog bootstrap circuit 4121, wherein the source follower 41231 is configured to operably receive the shared source voltage Vs, thus producing a feedback voltage Vfb. The source follower 41231 and the inverse phase amplification gain stage 41233 constitute a flipped voltage follower (FVF), wherein the FVF is configured to operably regulate the shared gate voltage Vg at a constant voltage level.

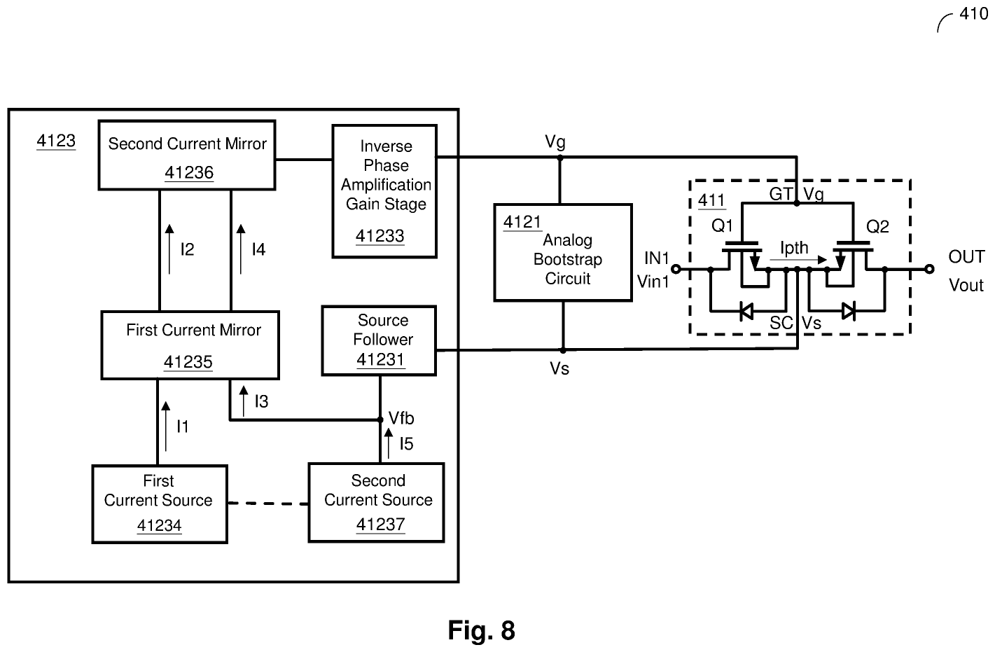

FIG. 8 shows a schematic diagram of a channel switch circuit 410 according to an exemplary embodiment of the present invention.

The feedback regulation circuit 4123 of this embodiment shown in FIG. 8 is similar to the feedback regulation circuit 4123 of the embodiment shown in FIG. 7, but is different in that: as compared to the feedback regulation circuit 4123 of the embodiment shown in FIG. 7, the feedback regulation circuit 4123 of this embodiment shown in FIG. 8 further includes: a first current mirror 41234, a first current source 41235, a second current mirror 41236 and a second current source 41237. The first current source 41234 is configured to operably provide a first current I1. The first current mirror 41235 is coupled to the first current source 41234, wherein the first current mirror 41235 is configured to operably generate a second current I2 and a third current I3 in a mirror fashion in accordance with the first current I1. The second current mirror 41236 is coupled to the first current mirror 41235 as well as the inverse phase amplification gain stage 41233, wherein the second current mirror 41236 is configured to operably generate a fourth current I4 through mirroring the second current I2. The second current source 41237 is coupled to the first current source 41234 and the source follower 41231, wherein the second current source 41237 is configured to operably generate a fifth current I5 correlated with the first current I1 according to the third current I3.

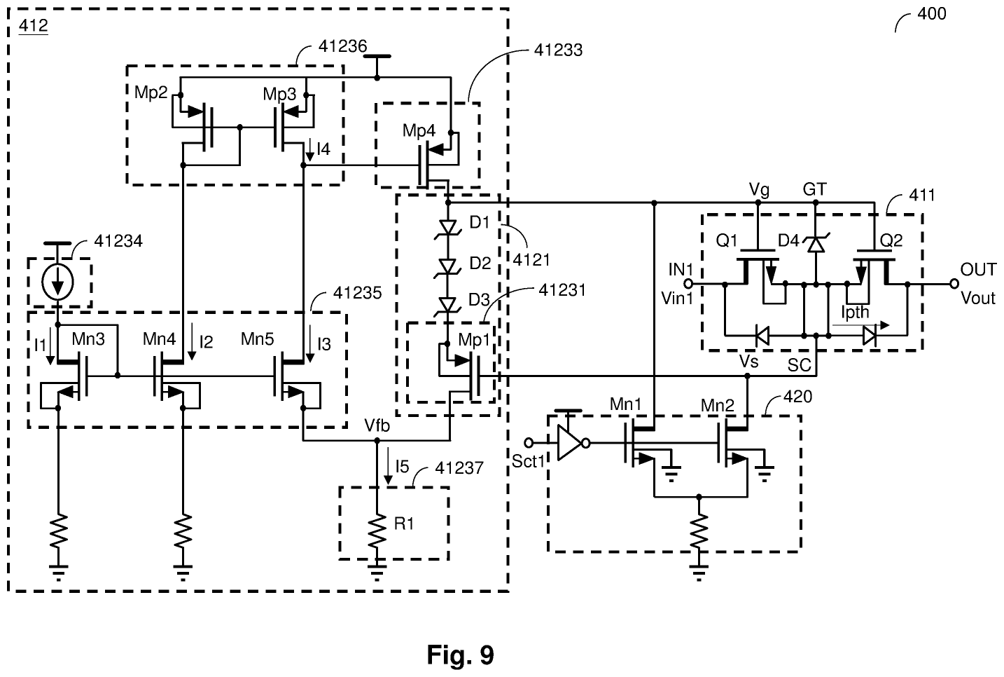

FIG. 9 shows a schematic diagram of a channel switch circuit 410 according to a specific exemplary embodiment of the present invention. As shown in FIG. 9, each channel switch circuit 410 incudes: a switch unit 411 and a control circuit 412. The channel switch circuit 410 of this embodiment shown in FIG. 9 is similar to the channel switch circuit 410 of the embodiment shown in FIG. 4, but is different in that: as compared to the channel switch circuit 410 of the embodiment shown in FIG. 4, the channel switch circuit 410 of this embodiment shown in FIG. 9 further includes: a Zener diode D4, which is coupled to the shared gate end GT and the shared source end SC, wherein the Zener diode D4 serves to restrict a voltage across the shared gate end GT and the shared source end SC from exceeding a reverse voltage threshold of the Zener diode D4. In a normal operation mode, the shared gate end GT and the shared source end SC remain considered as not being directly and electrically connected to each other. In addition, a body diode of the first switch Q1 and a body diode of the second switch Q2 are reversely connected in series to each other, such that in a case when the first switch Q1 and the second switch Q2 are both turned OFF, a non-zero current can be prevented from flowing through the current route Ipth.

As shown in FIG. 9, in addition to the plural channel switch circuits 410, the multiplexing channel switch selection circuit 400 further comprises: plural channel switch selection circuits 420, wherein each channel switch selection circuit 420 is coupled to the corresponding channel switch circuit 410. In this embodiment, the channel switch selection circuit 420 is configured to operably decide whether the channel switch circuit 410 corresponding to the channel switch selection circuit 420 is turned ON according to a corresponding channel selection signal Sct1. In this embodiment, the channel switch selection circuit 420 includes, for example but not limited to, a logic NOT gate, a MOS switch Mn1, a MOS switch Mn2 and a resistor, a coupling relationship among these aforementioned four elements are shown in FIG. 9. When the channel selection signal Sct1 is at a high potential, the MOS switch Mn1 and the MOS switch Mn2 are turned OFF, the conductive bias voltage Vc generated by the control circuit 412 is provided between the shared gate voltage Vg at the shared gate end GT and the shared source voltage Vs at the shared source end SC, thus turning ON the first switch Q1 and the second switch Q2. When the channel selection signal Sct1 is at a low potential, the MOS switch Mn1 and the MOS switch Mn2 are turned ON, the shared source end SC and the shared gate end GT are both electrically connected to a ground potential GND. As a result, in this case, each of the shared gate voltage Vg and the shared source voltage Vs has its own voltage level equal to a voltage level of the ground potential GND, so that the first switch Q1 and the second switch Q2 are both turned OFF.

As shown in FIG. 9, the analog bootstrap circuit 4121 includes: an unidirectional voltage difference unit 41211 and a MOS device 41213. The unidirectional voltage difference unit 41211 is constituted by a diode D1, a diode D2, a diode D3 and a diode D4, four of which are connected in series between the shared source end SC and the shared gate end GT. The MOS device 41213 is implemented as a P-type MOS device Mp1. A gate of the P-type MOS device Mp1 is coupled to the shared source end SC, whereas, a gate of the P-type MOS device Mp1 is coupled to a series connection of the diode D1, the diode D2, the diode D3 and the diode D4. When the first switch Q1 and the second switch Q2 are both turned ON, the P-type MOS device Mp1 is turned ON, thus obtaining a sum of a threshold voltage of the P-type MOS device Mp1 plus a forward conduction voltage of the series connection of the diode D1, the diode D2, the diode D3 and the diode D4 and to thereby render the accordingly obtained sum to function as the conductive bias voltage Vc.

As shown in FIG. 9, the first current source 41234 is configured to operably provide a first current I1. The first current mirror 41235 includes: MOS devices Mn3, Mn4 and Mn5. The first current mirror 41235 is coupled to the first current source 41234, wherein the first current mirror 41235 is configured to operably generate a second current I2 and a third current I3 in a mirror fashion in accordance with the first current I1. A ratio relationship lies among the first current I1, the second current I2 and the third current I3, which is a feature of a current mirror and which is well known to those skilled in the art, so the details thereof are not redundantly explained here. For example, in this embodiment, the first current I1, the second current I2 and the third current I3 has a same current level.

As shown in FIG. 9, the second current mirror 41236 is coupled to the first current mirror 41235 as well as the inverse phase amplification gain stage 41233, wherein the second current mirror 41236 is configured to operably generate a fourth current I4 through mirroring the second current I2. For example, in this embodiment, the second current I2 and the fourth current I4 has a same current level. In this embodiment, the second current mirror 41236 includes: a MOS device Mp2 and a MOS device Mp3. In this embodiment, the inverse phase amplification gain stage 41233 includes: a MOS device Mp4. The second current source 41237 is coupled to the first current source 41234 and the source follower 41231, wherein the second current source 41237 is configured to operably generate a fifth current I5 correlated with the first current I1 according to the third current I3. In this embodiment, the second current source 41237 includes: a resistor R1.

For example, a source voltage of the P-type MOS device Mp1 is enhanced as the shared gate voltage Vg is augmented due to all different types of factors (e.g., temperature), thus rendering a gate-source voltage of the P-type MOS device Mp1 to be raised and to thereby reduce a conduction resistance of the P-type MOS device Mp1, so that the feedback signal Vfb is raised. Consequently, in this case, a conduction resistance of a MOS device Mn5 is augmented as the gate-source voltage of a MOS device Mn5 is reduced. As a result, in this case, a drain voltage of the MOS device Mn5 is raised due to a situation when the third current I3 flowing through the MOS device Mn5 having an augmented conduction resistance. Because a drain of the MOS device Mn5 is electrically to a gate of a MOS device Mn4, a gate of the MOS device Mn4 is augmented, thus causing a gate-source voltage of the MOS device Mn4 to be reduced and to thereby decrease an ON current of the MOS device Mn4, whereby the shared gate voltage Vg is reduced. That is, when the shared gate voltage Vg is enhanced, the shared gate voltage Vg is being feedback-reduced. On the other hand, when the shared gate voltage Vg is decreased due to all different types of factors, the present invention can regulate the shared gate voltage Vg to become augmented via aforementioned negative feedback mechanism executed by the foregoing control circuit 412.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A multiplexing channel switch selection circuit, including:
a plurality of channel switch circuits, wherein the plurality of the channel switch circuits are coupled to a plurality of corresponding input ends and the plurality of the channel switch circuits are commonly coupled to an output end; each channel switch circuit comprising:
a switch unit including: a first switch and a second switch, wherein the first switch and the second switch are connected in series to a current route which lies between the corresponding input end and the output end, wherein in a situation when a channel selection signal selects the each channel switch circuit, the switch unit is configured to operably turn ON the first switch and the second switch based upon a shared gate voltage, so as to deliver an input voltage at the corresponding input end to the output end, so that the thus delivered input voltage becomes an output voltage at the output end, wherein a gate of the first switch and a gate of the second switch are commonly coupled to a shared gate end having the shared gate voltage thereat, and wherein a source of the first switch and a source of the second switch are commonly coupled to a shared source end having a shared source voltage thereat; and
a control circuit coupled between the shared source end and the shared gate end, wherein the control circuit includes:
an analog bootstrap circuit coupled between the shared source end and the shared gate end, wherein in a situation when the channel selection signal selects the each channel switch circuit, the analog bootstrap circuit is configured to operably supply a conductive bias voltage across between the shared source end and the shared gate end, so as to turn ON the first switch and the second switch; and
a feedback regulation circuit coupled to the analog bootstrap circuit, wherein the feedback regulation circuit is configured to operably feedback-regulate the shared gate voltage at a constant voltage level;
wherein in the situation when the channel selection signal selects the each channel switch circuit and in a situation when the each channel switch circuit operates in a steady state, a current flowing through the current route is a zero current;
wherein the shared gate voltage is equal to a sum of the shared source voltage plus the conductive bias voltage.

2. The multiplexing channel switch selection circuit as claimed in claim 1, wherein an output impedance at the output end is relatively at least ten times greater than an input impedance at the each input end.

3. The multiplexing channel switch selection circuit as claimed in claim 1, wherein the analog bootstrap circuit includes:
an unidirectional voltage difference unit coupled between the shared source end and the shared gate end, wherein the unidirectional voltage difference unit is configured to operably supply the conductive bias voltage.

4. The multiplexing channel switch selection circuit as claimed in claim 3, wherein the analog bootstrap circuit further includes:
a Metal-Oxide-Semiconductor (MOS) device, wherein a gate of the MOS device is coupled to the shared source end, whereas, a source or a drain of the MOS device is coupled to the unidirectional voltage difference unit, wherein when the first switch and the second switch are both turned ON, the MOS device is turned ON, so that a threshold voltage of the MOS device as well as the unidirectional voltage difference unit are both configured to operably supply the conductive bias voltage.

5. The multiplexing channel switch selection circuit as claimed in claim 3, wherein the unidirectional voltage difference unit includes: at least a PN diode, at least a Zener diode or at least a MOS diode.

6. The multiplexing channel switch selection circuit as claimed in claim 1, wherein the feedback regulation circuit includes:
a source follower coupled to the analog bootstrap circuit, wherein the source follower is configured to operably receive the shared source voltage, thus producing a feedback voltage; and
an inverse phase amplification gain stage, wherein the source follower and the inverse phase amplification gain stage constitute a flipped voltage follower (FVF), wherein the FVF is configured to operably regulate the shared gate voltage at the constant voltage level.

7. The multiplexing channel switch selection circuit as claimed in claim 6, wherein the feedback regulation circuit includes:
a first current source, which is configured to operably provide a first current;
a first current mirror coupled to the first current source, wherein the first current mirror is configured to operably generate a second current and a third current in a mirror fashion in accordance with the first current;
a second current mirror coupled to the first current mirror as well as the inverse phase amplification gain stage, wherein the second current mirror is configured to operably generate a fourth current through mirroring the second current; and
a second current source coupled to the first current source and the source follower, wherein the second current source is configured to operably generate a fifth current correlated with the first current according to the third current.

8. A control circuit of a multiplexing channel switch selection circuit, which is configured to operably control a channel switch circuit of the multiplexing channel switch selection circuit, wherein the multiplexing channel switch selection circuit, includes: a plurality of channel switch circuits, wherein the plurality of the channel switch circuits are coupled to a plurality of corresponding input ends and the plurality of the channel switch circuits are commonly coupled to an output end; and wherein each channel switch circuit further includes a switch unit having: a first switch and a second switch, wherein the first switch and the second switch are connected in series to a current route which lies between the corresponding input end and the output end, wherein in a situation when a channel selection signal selects the each channel switch circuit, the switch unit is configured to operably turn ON the first switch and the second switch based upon a shared gate voltage, so as to deliver an input voltage at the corresponding input end to the output end, so that the thus delivered input voltage becomes an output voltage at the output end, wherein a gate of the first switch and a gate of the second switch are commonly coupled to a shared gate end having the shared gate voltage thereat, and wherein a source of the first switch and a source of the second switch are commonly coupled to a shared source end having a shared source voltage thereat; the control circuit of the multiplexing channel switch selection circuit comprising:
an analog bootstrap circuit coupled between the shared source end and the shared gate end, wherein in a situation when the channel selection signal selects the each channel switch circuit, the analog bootstrap circuit is configured to operably supply a conductive bias voltage across between the shared source end and the shared gate end, so as to turn ON the first switch and the second switch; and
a feedback regulation circuit coupled to the analog bootstrap circuit, wherein the feedback regulation circuit is configured to operably feedback-regulate the shared gate voltage at a constant voltage level;
wherein in the situation when the channel selection signal selects the each channel switch circuit and in a situation when the each channel switch circuit operates in a steady state, a current flowing through the current route is a zero current;
wherein the shared gate voltage is equal to a sum of the shared source voltage plus the conductive bias voltage.

9. The control circuit as claimed in claim 8, wherein an output impedance at the output end is relatively at least ten times greater than an input impedance at the each input end.

10. The control circuit as claimed in claim 8, wherein the analog bootstrap circuit includes:
an unidirectional voltage difference unit coupled between the shared source end and the shared gate end, wherein the unidirectional voltage difference unit is configured to operably supply the conductive bias voltage.

11. The control circuit as claimed in claim 10, wherein the analog bootstrap circuit further includes:
a Metal-Oxide-Semiconductor (MOS) device, wherein a gate of the MOS device is coupled to the shared source end, whereas, a source or a drain of the MOS device is coupled to the unidirectional voltage difference unit, wherein when the first switch and the second switch are both turned ON, the MOS device is turned ON, so that a threshold voltage of the MOS device as well as the unidirectional voltage difference unit are both configured to operably supply the conductive bias voltage.

12. The control circuit as claimed in claim 10, wherein the unidirectional voltage difference unit includes: at least a PN diode, at least a Zener diode or at least a MOS diode.

13. The control circuit as claimed in claim 8, wherein the feedback regulation circuit includes:
a source follower coupled to the analog bootstrap circuit, wherein the source follower is configured to operably receive the shared source voltage, thus producing a feedback voltage; and
an inverse phase amplification gain stage, wherein the source follower and the inverse phase amplification gain stage constitute a flipped voltage follower (FVF), wherein the FVF is configured to operably regulate the shared gate voltage at the constant voltage level.

14. The control circuit as claimed in claim 13, wherein the feedback regulation circuit includes:
a first current source, which is configured to operably provide a first current;
a first current mirror coupled to the first current source, wherein the first current mirror is configured to operably generate a second current and a third current in a mirror fashion in accordance with the first current;
a second current mirror coupled to the first current mirror as well as the inverse phase amplification gain stage, wherein the second current mirror is configured to operably generate a fourth current through mirroring the second current; and
a second current source coupled to the first current source and the source follower, wherein the second current source is configured to operably generate a fifth current correlated with the first current according to the third current.

15. A control method of a multiplexing channel switch selection circuit, which is configured to operably control a channel switch circuit of the multiplexing channel switch selection circuit, wherein the multiplexing channel switch selection circuit, includes: a plurality of channel switch circuits, wherein the plurality of the channel switch circuits are coupled to a plurality of corresponding input ends and the plurality of the channel switch circuits are commonly coupled to an output end; and wherein each channel switch circuit further includes a switch unit having: a first switch and a second switch, wherein the first switch and the second switch are connected in series to a current route which lies between the corresponding input end and the output end, wherein in a situation when a channel selection signal selects the each channel switch circuit, the switch unit is configured to operably turn ON the first switch and the second switch based upon a shared gate voltage, so as to deliver an input voltage at the corresponding input end to the output end, so that the thus delivered input voltage becomes an output voltage at the output end, wherein a gate of the first switch and a gate of the second switch are commonly coupled to a shared gate end having the shared gate voltage thereat, and wherein a source of the first switch and a source of the second switch are commonly coupled to a shared source end having a shared source voltage thereat; the control method of the multiplexing channel switch selection circuit comprising following steps:
in a situation when the channel selection signal selects the each channel switch circuit, supplying an conductive bias voltage across between the shared source end and the shared gate end, so as to turn ON the first switch and the second switch; and
feedback-regulating the shared gate voltage at a constant voltage level;
wherein in the situation when the channel selection signal selects the each channel switch circuit and in a situation when the each channel switch circuit operates in a steady state, a current flowing through the current route is a zero current;
wherein the shared gate voltage is equal to a sum of shared the source voltage plus the conductive bias voltage.

16. The control method as claimed in claim 15, wherein an output impedance at the output end is relatively at least ten times greater than an input impedance at the each input end.

17. The control method as claimed in claim 15, wherein the step for supplying the conductive bias voltage includes following steps:
providing an unidirectional voltage difference unit, which is coupled between the shared source end and the shared gate end, wherein the unidirectional voltage difference unit is configured to operably supply the conductive bias voltage.

18. The control method as claimed in claim 17, wherein the step for supplying the conductive bias voltage further includes following steps:
providing a Metal-Oxide-Semiconductor (MOS) device, wherein a gate of the MOS device is coupled to the shared source end, whereas, a source or a drain of the MOS device is coupled to the unidirectional voltage difference unit, wherein when the first switch and the second switch are both turned ON, the MOS device is turned ON, so that a threshold voltage of the MOS device as well as the unidirectional voltage difference unit are both configured to operably supply the conductive bias voltage.

19. The control method as claimed in claim 17, wherein the unidirectional voltage difference unit includes: at least a PN diode, at least a Zener diode or at least a MOS diode.

20. The control method as claimed in claim 15, wherein the step for feedback-regulating the shared gate voltage at the constant voltage level includes following steps:
receiving the shared source voltage, thus producing a feedback voltage; and
regulating the shared gate voltage at the constant voltage level via a flipped voltage follower (FVF).
